(19) United States
(12) Patent Application Publication
(10) Pub. No.: US 2010/0178750 A1
(43) Pub. Date: Jul. 15, 2010

(54) METHOD FOR PRODUCING BONDED WAFER

(75) Inventors: Satoshi Murakami, Tokyo (JP); Akihiko Endo, Tokyo (JP); Nobuyuki Morimoto, Tokyo (JP); Hideki Nishihata, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/503,784

(22) Filed: Jul. 15, 2009

(30) Foreign Application Priority Data
Jul. 17, 2008 (JP) 2008-185921

(51) Int. Cl. H01L 21/18

(52) U.S. Cl. 438/459; 257/E21.088

(57) ABSTRACT

A bonded wafer is produced by removing a part or all of native oxide films formed on each surface of both a wafer for active layer and a wafer for support substrate to be bonded; forming a uniform oxide film with a thickness of less than 5 nm on at least one surface of these wafers by a given oxide film forming method; bonding the wafer for active layer to the wafer for support substrate through the uniform oxide film; thinning the wafer for active layer; and subjecting the bonded wafer to a given heat treatment in a non-oxidizing atmosphere to substantially remove the uniform oxide film existing in the bonding interface.

### BACKGROUND

1. Field of the Invention

This invention relates to a method for producing a bonded wafer wherein a uniform oxide film is formed on an interface(s) between a wafer for active layer and a wafer for support substrate to be bonded and the uniform oxide film is substantially removed by subsequent heat treatment to directly bond the wafer for active layer and the wafer for support substrate without the oxide film.

2. Description of the Related Art

A bonded wafer normally means a bonded SOI wafer. As a production method thereof is mentioned, for instance, a method wherein an oxidized wafer for active layer is bonded to a wafer for support substrate and thereafter a surface of the wafer for active layer is thinned to a given thickness by grinding and polishing as disclosed in a literature, “Science of Silicon”, edited by UCS Semiconductor Substrate Technology Workshop, published by REALIZE INC. on Jun. 28, 1996, pp 459-462, and an ion implantation-isolation method or a so-called smart cut (Smart Cut (registered trademark)) method comprising a step of implanting ions of a light element such as hydrogen, helium or the like into a wafer for active layer at a given depth position to form an ion implanted layer, a step of bonding the wafer for active layer to a wafer for support substrate through an insulating film, a step of exfoliating at the ion implanted layer, and a step of thinning a portion of the active layer exposed at a state bonded to the wafer for support substrate by exfoliation to form an active layer of a given thickness as disclosed in JP-A-H05-211128.

Also, as a wafer used for a low power consumption device in next generation or later, there is a bonded wafer produced by a novel method wherein a wafer for active layer and a wafer for support substrate are bonded directly without an insulating film and the wafer for active layer is thinned and then subjected to a heat treatment as described, for example, in JP-A-2000-36445. The bonded wafer produced by this production method and having no oxide film is noticed as a beneficial wafer in view of simplification of a production process of a composite crystal face substrate and improvement of performances thereof.

However, since the oxide film on a bonding interface of the bonded wafer bonded directly without the insulating film is locally concentrated to form island-shaped oxides in steps of producing the bonded wafer (particularly, a heat treatment step), there is a problem that traces of the island-shaped oxides remain though the island-shaped oxides can be removed at the subsequent heat treatment step. These oxide traces are not preferable in appearance when the bonded wafer is used as a product because the traces can be seen through the wafer surface when the active layer is particularly thin. Furthermore, the traces of the island-shaped oxides may be recognized as particles by a laser surface detector for accounting particles adhered to the wafer surface, resulting in a problem that a process management can not be conducted at a device step by the surface detector. Moreover, there is another problem that the heat treatment at a higher temperature for a long time is required for removing the island-shaped oxide.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

It is, therefore, an object of the invention to provide a method for producing a bonded wafer wherein a uniform oxide film of a given thickness is formed on at least one of a wafer for active layer and a wafer for support substrate by a given method and then subjected to bonding, thinning and heat-treating steps, whereby the uniform oxide film can be substantially removed by the heat treatment at a lower temperature or for a shorter time as compared with the conventional method.

The summary and construction of the invention for achieving the above object are as follows.

(1) A method for producing a bonded wafer, which comprises removing a part or a full of native oxide films formed on each surface of both a wafer for active layer and a wafer for support substrate to be bonded; forming a uniform oxide film with a thickness of less than 5 nm on at least one surface of these wafers by a given oxide film forming method; bonding the wafer for active layer to the wafer for support substrate through the uniform oxide film; thinning the wafer for active layer; and subjecting the bonded wafer to a given heat treatment in a non-oxidizing atmosphere to substantially remove the uniform oxide film existing in the bonding interface.

(2) A method for producing a bonded wafer according to the item (1), wherein a thickness of the thinned wafer for active layer is not more than 500 nm.

(3) A method for producing a bonded wafer according to the item (1), wherein the given oxide film forming method is a thermal oxidation.

(4) A method for producing a bonded wafer according to the item (1), wherein an oxygen concentration of at least one of the wafer for active layer and the wafer for support substrate is not more than 1.6×10¹⁸ atoms/cm³.

(5) A method for producing a bonded wafer according to the item (1), wherein the thinning of the wafer is conducted by using a hydrogen ion implantation-isolation method or an etching/polishing stop method through an oxygen ion implantation.

(6) A method for producing a bonded wafer according to the item (1), wherein the heat treatment is conducted within a temperature range of from 1050° C. to 1250° C. for from 0.5 to 50 hours.

(7) A method for producing a bonded wafer according to the item (1), wherein the non-oxidizing atmosphere is an atmosphere of Ar, H₂ or a mixed gas thereof.

(8) A method for producing a bonded wafer according to the item (1), wherein each of the wafer for active layer and the wafer for support substrate is a silicon single crystal, and each surface of the wafers to be bonded is a different orientation of (100), (110) or (111) face.

According to the invention, it is possible to provide a method for producing a bonded wafer in which the oxide film existing in the bonding interface can be substantially removed by a heat treatment at a lower temperature or for a shorter time as compared with the conventional method.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a flow chart showing steps of producing a bonded wafer according to the production method of the invention, wherein (a) shows a wafer for active layer and a wafer for support substrate each provided with a native oxide film, and (b) shows the wafer for active layer and the wafer for support substrate after the removal of the native oxide film, and (c) shows the wafer for active layer provided with a uniform oxide film of less than 5 nm and the wafer for support substrate after the removal of the native oxide film, and (d) shows a state of bonding both the wafers shown in (c), and (e) shows the bonded wafer after grinding or exfoliating a part of the wafer for active layer, and (f) shows a state of subjecting the bonded wafer to a heat treatment to remove the oxide film from the bonding interface;

FIG. 2 is a view illustrating a bonding interface state before a heat treatment of a bonded wafer obtained by directly bonding a wafer for active layer to a wafer for support substrate through a native oxide film as known in the prior art, wherein (a) is a schematically cross-sectional view showing a part of the bonded wafer, and (b) is a perspective view showing a surface of the bonded wafer;

FIG. 3 is a view illustrating a bonding interface state after a heat treatment of a bonded wafer obtained by directly bonding a wafer for active layer to a wafer for support substrate through a native oxide film as known in the prior art, wherein (a) is a schematically cross-sectional view showing a part of the bonded wafer, and (b) is a perspective view showing a surface of the bonded wafer; and

FIGS. 4A and 4B are photograph of each sample of Example 1 and Comparative Example 1 after the removal of an oxide film, wherein FIG. 4A shows a sample of Example 1, and FIG. 4B shows a sample of Comparative Example 1.

### DETAILED DESCRIPTION

While illustrative embodiments have been illustrated and described, it will be appreciated that various changes can be made therein without departing from the spirit and scope of the invention.

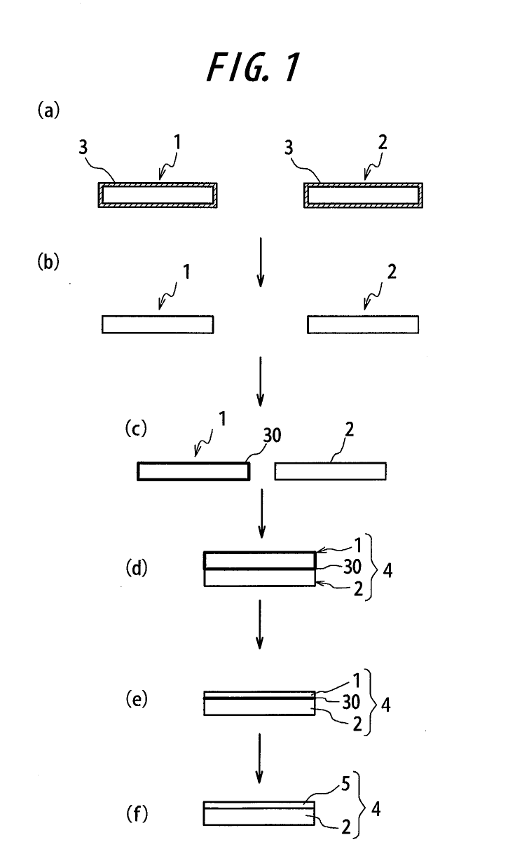

FIG. 1 is a flow chart showing a method for producing a bonded wafer according to the invention.

Concretely, the production method according to the invention comprises steps of removing native oxide films 3 (FIG. 1(a)) formed on both surfaces of a wafer for active layer 1 and a wafer for support substrate 2 (FIG. 1(b)); forming a uniform oxide film 30 with a thickness of less than 5 nm on at least one surface of these wafers 1, 2 (a surface of the wafer for active layer 1 in FIG. 1(c)) by a given oxide film forming method (FIG. 1(c)); bonding the wafer for active layer 1 to the wafer for support substrate 2 through the uniform oxide film 30 (FIG. 1(d)); thinning the wafer for active layer 1 to a thickness of not more than 500 nm to form an active layer 5 (FIG. 1(e)); and subjecting the bonded wafer 4 to a heat treatment in a non-oxidizing atmosphere under given conditions to substantially remove the uniform oxide film 30 existing in the bonding interface (FIG. 1(f)).

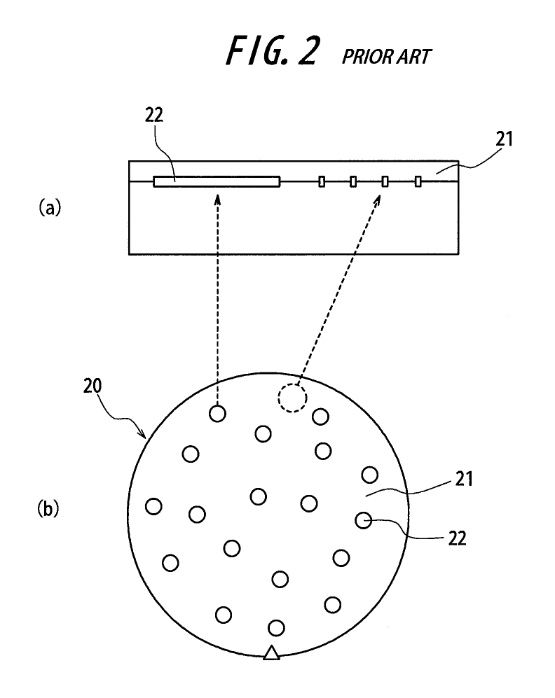

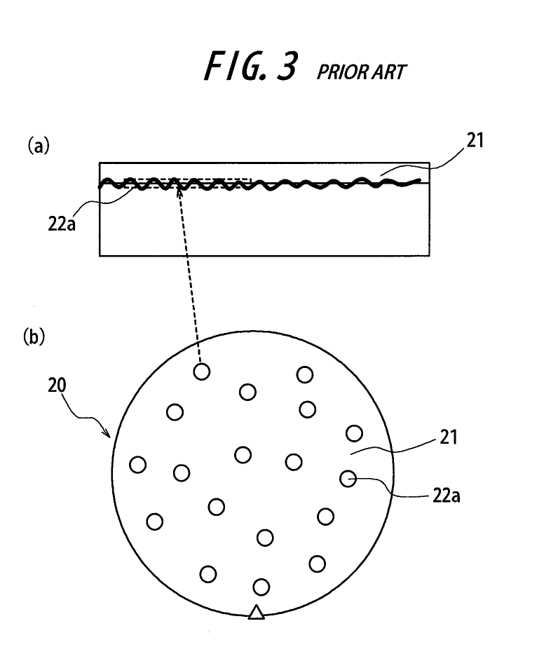

FIGS. 2 and 3 are schematic views of bonding interface states before and after a heat treatment of prior art bonded wafer obtained by directly bonding a wafer for active layer to a wafer for support substrate through a native oxide film. In the conventional bonded wafer 20, thin native oxide films having a thickness of not more than 2 nm are formed on each surface of the wafer for active layer and the wafer for support substrate before the bonding. When both the wafers are bonded to each other, the native oxide films are aggregated in a bonding interface 21 to form island-shaped oxides 22 (FIGS. 2(a), (b)). Even after the island-shaped oxides 22 are removed by subsequent heat treatment, traces 22a of the oxides remain in the bonding interface 21 (FIGS. 3(a), (b)). When the active layer is as thin as not more than 500 nm, the traces are seen through the surface of the wafer, which is a problem in appearance (design). Furthermore, the traces of the island-shaped oxides may also be recognized as particles in a laser surface detector for accounting particles adhered to the wafer surface, so that there is a possibility of causing a problem that a process management can not be conducted at a device step by the surface detector.

The inventors have made various studies for solving the above problems and found that when the native oxide films formed on both surfaces of the wafer for active layer 1 and the wafer for support substrate 2 are removed and then a uniform oxide film 30 of less than 5 nm in thickness is immediately and positively formed on at least one surface of these wafers 1, 2 by a given oxide film forming method, preferably a thermal oxidation method as shown in FIGS. 1(a) to (c), the uniform oxide film 30 is existent in the bonding interface before the heat treatment and can be diffused outward and substantially removed by the subsequent heat treatment and hence the traces of the oxide film are not existent in the bonding interface. Also, it has been found that since the thickness of the uniform oxide film 30 is less than 5 nm and the thickness of the active layer is not more than 500 nm, a heat treating time required for diffusing oxygen in the uniform oxide film outward to remove the uniform oxide film can be largely reduced. Furthermore, it has been found that the production cost can be largely reduced because the heat treatment is conducted at a temperature of not higher than 1250° C. without using a specific heat-treating means for conducting a high-temperature treatment.

(Step of Removing Native Oxide Film)

In the production method according to the invention, as shown in FIG. 1(b), the native oxide films 3 (FIG. 1(a)) formed on both surfaces of the wafer for active layer 1 and the wafer for support substrate 2 are removed. The removal of the native oxide film 3 can be conducted, for example, by a wet etching with HF solution, a dry etching or the like. When the full native oxide film is removed, there may be caused a problem that an active silicon face is exposed and hence particles are easily adhered thereto and voids as a bonding defect are apt to be caused in the subsequent bonding step, so that it is important to leave a part (not more than 1 nm) of the native oxide film depending on the cleanliness of the environment.

(Step of Forming Uniform Oxide Film)

In the production method according to the invention, as shown in FIG. 1(c), a uniform oxide film 30 with a thickness of less than 5 nm is formed on at least one surface of the wafer for active layer 1 and the wafer for support substrate 2 by a given oxide film forming method immediately after the step of removing the native oxide film 3. By forming the uniform oxide film 30 is developed an effect that the oxide film 30 can be removed by a heat treatment for a shorter time as compared with the conventional method as mentioned above but also even when the thickness of the active layer 5 is not more than 500 nm, the trace of the island-shaped oxide can be eliminated in the bonding interface. Even if the thickness of the oxide film is not less than 5 nm, it is possible to eliminate island traces of SiO₂, but the heat treatment for vanishing the oxide film in a reducing atmosphere is required to be a higher temperature and a longer time but also the surface of the bonded wafer becomes undesirably rough by oxygen released from the surface of the bonded wafer, actually SiOx having a high vapor pressure released by the reaction with silicon.

The given oxide film forming method is not limited as long as it can form a uniform oxide film of less than 5 nm in thickness, but a thermal oxidization is preferable in a point that it can be controlled to form a thin and uniform oxide film. The thermal oxidization is a method of forming an oxide film by placing the wafer for active layer 1 and/or the wafer for support substrate 2 after the removal of a part or a whole of the native oxide film in an oxidation furnace at a high temperature of 600 to 1200° C. and reacting with oxygen. Particularly, it is more preferable to use a dry oxidization flowing a highly-purity oxygen gas. Also, it is possible to use an oxygen gas diluted with a nitrogen gas because a growth rate of the oxide film is large depending on the heat-treating temperature and it is difficult to control the thickness of less than 5 nm.

Furthermore, at least one of the wafer for active layer 1 and the wafer for support substrate 2 is preferable to have an oxygen concentration of not more than 1.6×10¹⁸ atoms/cm³ (old-ASTM conversion). When the oxygen concentration exceeds 1.6×10¹⁸ atom/cm³, it is required to conduct the heat treatment at a higher temperature for a longer time for an outward diffusion of oxygen, and also there is a risk that oxygen precipitates are formed in the active layer during the device production heat treatment to deteriorate device properties.

(Step of Bonding)

In the production method according to the invention, as shown in FIG. 1(d), the wafer for active layer 1 is bonded to the wafer for support substrate 2 through the uniform oxide film 30 after the formation of the uniform oxide film 30. It is preferable to conduct a cleaning before the bonding in order to prevent an occurrence of bonding defects (voids) due to particles existing in the bonding face. For example, SC1 (ammonia+hydrogen peroxide solution) cleaning+SC2 (hydrochloric acid+hydrogen peroxide solution) cleaning, or HF cleaning+ozone cleaning can be applied, whereby there can be obtained a bonded wafer 4 having the uniform oxide film 30.

Also, the bonding faces of two silicon wafers may be a combination of (100), (110), or (111) face. When the crystal orientation in the bonding faces is different, a size of island-shaped oxide is larger than the case that the crystal orientation is same. For example, the size of SiO₂ island is 100 to 200 μm in the bonding of (100) faces, and 100 to 500 μm in the bonding of (100) face and (110) face. Therefore, the invention is particularly effective in the bonding between the faces having different crystal orientations because the effect of suppressing the trace due to the native oxide film is remarkably developed. Moreover, the trace means that the oxide film is decomposed into silicon and oxygen during the vanishing of the oxide film and the resulting oxygen is diffused to the surface of the bonded wafer by outward diffusion and reacted with silicon to form SiOx having a high vapor pressure, which jumps outward from the surface of the wafer for active layer 1 to thereby roughen the surface so as to remain as a trace.

(Step of Thinning)

In the production method according to the invention, as shown in FIG. 1(e), the wafer for active layer 1 after the bonding step is thinned to a thickness of not more than 500 nm to form an active layer 5. There is an effect of reducing the time required for the subsequent heat treatment by rendering the thickness of the active layer into not more than 500 nm, and an effect of suppressing the formation of oxygen precipitates and the growth of SiO₂ islands in the bonding interface due to the dissolved oxygen by restricting an absolute amount of the dissolved oxygen existing in the wafer for active layer which is increased as the thickness becomes thicker.

The method of thinning the active layer of the bonded wafer 4 (FIG. 1(e)) is not particularly limited as long as the thickness can be controlled to not more than 500 nm, and includes a method of grinding the wafer for active layer 1 and a method of removing the wafer for active layer by etching and so on. However, the use of an ion implantation-isolation method is particularly preferable because it is excellent in the cost performance since a portion of the wafer for active layer obtained by exfoliating the portion of the wafer for active layer from the bonded wafer can be recycled and it can ensure the thickness uniformity of the bonded wafer 4 without grinding or the like. The ion implantation-isolation method is a thinning method wherein a light element gas such as a hydrogen gas or the like is implanted from the surface of the wafer for active layer 1 into a given depth position to form an ion implanted layer and the wafer for active layer 1 is bonded to the wafer for support substrate 2 and then the resulting bonded wafer is subjected to a heat treatment at about 500° C. to exfoliate the wafer for active layer 1 at the ion implanted layer.

Alternatively, when etching or grinding/polishing is selected as a thinning method, it is preferable to use an oxygen implanted layer formed by implanting oxygen into a given depth position of the wafer for active layer 1 as an etching stop layer or a polishing stop layer. In this case, an accuracy in the thinning of the active layer can be enhanced.

(Step of Heat Treatment)

In the production method according to the invention, as shown in FIG. 1(f), the bonded wafer 4 after the thinning step is subjected to a heat treatment in a non-oxidizing atmosphere under given conditions. By this heat treatment can be substantially removed the uniform oxide film 30 existing in the bonding interface to obtain a bonded wafer having no oxide film at its bonding interface. The term “substantially remove” used herein means that the thickness of the oxide film is not more than 1 nm and the vanishing is caused to an extent that the oxide film can not be observed as measured with a cross-sectional TEM.

The heat treatment is preferably conducted within a temperature range of from 1050° C. to 1250° C. for from 0.5 to 50 hours. More preferably, the temperature and the time in the heat treatment are from 1150 to 1200° C. and from 1 to 2 hours. In the production method according to the invention, since the thicknesses of the uniform oxide film 30 and the active layer are as thin as less than 5 nm and not more than 500 nm, respectively, the heat treating temperature and time can be reduced as compared with those of the conventional production method.

Also, the non-oxidizing atmosphere for the heat treatment is preferable to be an atmosphere of Ar, H₂ or a mixed gas thereof. A mixed gas of Ar or H₂ and N₂ may be used as a non-oxidizing atmosphere for decomposing SiO₂ islands, but causes a phenomenon of roughening the wafer surface due to the formation of a nitride film, so that the use of such a mixed gas is not preferable. On the other hand, the atmosphere of Ar, H₂ or the mixed atmosphere thereof can suppress the above surface roughening.

Although the above is described with respect to only one embodiment of the invention, various modifications may be made without departing from the scope of the appended claims.

### Example 1

In Example 1, a silicon wafer having a size of 300 mm and a crystal orientation of (110) face is provided as a wafer for active layer and a silicon wafer having the same size and a crystal orientation of (100) face is provided as a wafer for support substrate, and native oxide film formed on the surface of each wafer is removed by immersing the wafer into a 0.5% HF solution for 30 seconds, and then the wafer for active layer is subjected to a heat treatment at 800° C. in an atmosphere of 75% nitrogen and 25% oxygen for 13 minutes to form a uniform thermal oxide film having a thickness of 2.7 nm on the surface of the wafer. Then, hydrogen ions are implanted so as to render an implantation peak into a depth position of 500 nm from the surface of the wafer for active layer to form a hydrogen ion implanted layer, and thereafter the wafer for active layer is bonded to the wafer for support substrate through the uniform thermal oxide film. Next, a part of the wafer for active layer is exfoliated at the hydrogen ion implanted layer by conducting a heat treatment at 500° C. in an oxygen atmosphere for 30 minutes to obtain a bonded wafer having an active layer with a thickness of 300 nm. Thereafter, a heat treatment is conducted in an atmosphere of 100% Ar under heat-treating temperature and time shown in Table 1 for removing the uniform thermal oxide film existing on the bonding interface.

### Example 2

In Example 2, a bonded wafer is produced by the same steps as in Example 1 except that the thickness of the uniform thermal oxide film formed on the wafer for active layer is 4.5 nm.

### Example 3

In Example 3, a silicon wafer having a size of 300 mm and a crystal orientation of (110) face is provided as a wafer for active layer and a silicon wafer having the same size and a crystal orientation of (100) face is provided as a wafer for support substrate, and native oxide film formed on the surface of each wafer is removed by immersing the wafer into a 0.5% HF solution for 30 seconds, and then the wafer for active layer is subjected to a heat treatment at 800° C. in an atmosphere of 75% nitrogen and 25% oxygen for 13 minutes to form a uniform thermal oxide film having a thickness of 2.7 nm on the surface of the wafer. Then, oxygen ions are implanted so as to render an implantation peak into a depth position of 450 nm from the surface of the wafer for active layer to form a polishing stop layer, and thereafter the wafer for active layer is bonded to the wafer for support substrate through the uniform thermal oxide film. Next, the wafer for active layer is polished up to the polishing stop layer to obtain a bonded wafer having an active layer with a thickness of 350 nm. Thereafter, a heat treatment is conducted in an atmosphere of 100% Ar under heat-treating temperature and time shown in Table 1 for removing the uniform thermal oxide film existing on the bonding interface.

### Example 4

In Example 4, a bonded wafer is produced by the same steps as in Example 3 except that the thickness of the uniform thermal oxide film formed on the wafer for active layer is 4.5 nm.

### Comparative Example 1

In Comparative Example 1, a bonded wafer is produced by the same steps as in Example 1 except that the thickness of the uniform thermal oxide film formed on the wafer for active layer is 6.2 nm.

### Comparative Example 2

In Comparative Example 2, a bonded wafer is produced by the same steps as in Example 3, except that the thickness of the uniform thermal oxide film formed on the wafer for active layer is 6.2 nm.

Evaluation Method

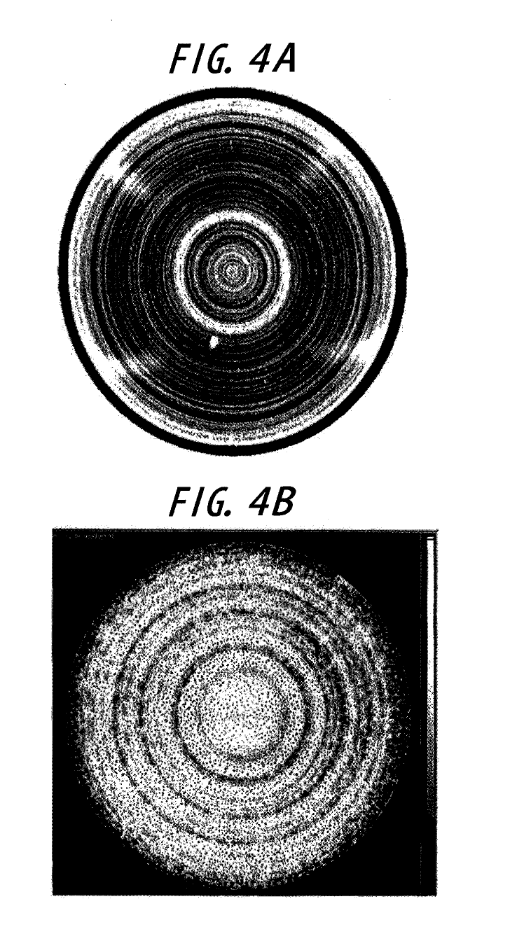

With respect to the bonded wafer samples produced above, the presence or absence of the uniform thermal oxide film is examined by observing a cross-section of the bonded wafer subjected to the heat treatment at 1100° C., 1150° C. or 1200° C. The results are shown in Table 1. Also, with respect to the samples of Example 1 and Comparative Example 1, states after the removal of the oxide film from the bonding interface are photographed for observation. Photographs of the samples from Example 1 and Comparative Example 1 are shown in FIGS. 4A and 4B, respectively.

TABLE 1

| | | | | Heat- | | | | | | | |
|---|---|---|---|---|---|---|---|---|---|---|---|
| | Thickness | | Atmosphere | treating | | | | | | | |
| | of oxide | Method of thinning | of heat | temperature | Heat-treating time (hour) | | | | | | |
| | film (nm) | active layer | treatment | (° C.) | 0.5 | 1 | 2 | 12 | 24 | 48 | 50 |
| Example 1 | 2.7 | Ion implantation- | Ar | 1050 | X | X | X | X | X | ◯ | ◯ |
| | | isolation method | | 1100 | X | X | X | ◯ | ◯ | ◯ | ◯ |
| | | | | 1150 | X | ◯ | ◯ | ◯ | ◯ | ◯ | ◯ |
| | | | | 1200 | X | ◯ | ◯ | ◯ | ◯ | ◯ | ◯ |
| | | | | 1250 | ◯ | ◯ | ◯ | ◯ | ◯ | ◯ | ◯ |
| Example 2 | 4.5 | Ion implantation- | Ar | 1050 | X | X | X | X | X | ◯ | ◯ |
| | | isolation method | | 1100 | X | X | X | ◯ | ◯ | ◯ | ◯ |
| | | | | 1150 | X | X | ◯ | ◯ | ◯ | ◯ | ◯ |
| | | | | 1200 | X | ◯ | ◯ | ◯ | ◯ | ◯ | ◯ |
| | | | | 1250 | ◯ | ◯ | ◯ | ◯ | ◯ | ◯ | ◯ |
| Example 3 | 2.7 | Etching/polishing | Ar | 1050 | X | X | X | X | X | ◯ | ◯ |
| | | stop by implanting | | 1100 | X | X | X | ◯ | ◯ | ◯ | ◯ |
| | | oxygen ion | | 1150 | X | ◯ | ◯ | ◯ | ◯ | ◯ | ◯ |
| | | | | 1200 | X | ◯ | ◯ | ◯ | ◯ | ◯ | ◯ |
| | | | | 1250 | ◯ | ◯ | ◯ | ◯ | ◯ | ◯ | ◯ |
| Example 4 | 4.5 | Etching/polishing | Ar | 1050 | X | X | X | X | X | ◯ | ◯ |
| | | stop by implanting | | 1100 | X | X | X | ◯ | ◯ | ◯ | ◯ |
| | | oxygen ion | | 1150 | X | X | ◯ | ◯ | ◯ | ◯ | ◯ |
| | | | | 1200 | X | ◯ | ◯ | ◯ | ◯ | ◯ | ◯ |
| | | | | 1250 | ◯ | ◯ | ◯ | ◯ | ◯ | ◯ | ◯ |
| Comparative | 6.2 | Ion implantation- | Ar | 1050 | X | X | X | X | X | X | ◯ |
| Example 1 | | isolation method | | 1100 | X | X | X | ◯ | ◯ | ◯ | ◯ |
| | | | | 1150 | X | X | ◯ | ◯ | ◯ | ◯ | ◯ |
| | | | | 1200 | X | ◯ | ◯ | ◯ | ◯ | ◯ | ◯ |
| | | | | 1250 | ◯ | ◯ | ◯ | ◯ | ◯ | ◯ | ◯ |
| Comparative | 6.2 | Etching/polishing | Ar | 1050 | X | X | X | X | X | X | ◯ |
| Example 2 | | stop by implanting | | 1100 | X | X | X | ◯ | ◯ | ◯ | ◯ |
| | | oxygen ion | | 1150 | X | X | ◯ | ◯ | ◯ | ◯ | ◯ |
| | | | | 1200 | X | ◯ | ◯ | ◯ | ◯ | ◯ | ◯ |
| | | | | 1250 | ◯ | ◯ | ◯ | ◯ | ◯ | ◯ | ◯ |

* ◯: oxide film vanishs, X: oxide film remains

As seen from the results of Table 1, the uniform oxide film in the bonding interface is removed in all of the bonded wafers as the heat-treating temperature becomes higher. Also, it is found out that Examples 1 to 4 having the thickness of oxide film in the bonding interface of less than 5nm are shorter in the time required for the vanishing of the oxide film than those of Comparative Examples 1 and 2 having the thickness of the oxide film of more than 5 nm. Furthermore, as to the state after the vanishing of the oxide film, traces of island-shaped oxides are hardly observed in Example 1 as shown in FIG. 4A, while many traces of island-shaped oxides are observed at a state of black spots in Comparative Example 1 as shown in FIG. 4B.

According to the invention, it is possible to provide a method for producing a bonded wafer in which the oxide film existing in the bonding interface can be substantially removed by a heat treatment at a lower temperature or for a shorter time as compared with the conventional method.

The embodiments of the invention in which an exclusive property or privilege is claimed are defined as follows:

1. A method for producing a bonded wafer, which comprises removing at least a part of native oxide films formed on each surface of both a wafer for active layer and a wafer for support substrate to be bonded; forming a uniform oxide film with a thickness of less than 5 nm on at least one surface of the wafers; bonding the wafer for active layer to the wafer for support substrate through the uniform oxide film; thinning the wafer for active layer; and subjecting the bonded wafer to a given heat treatment in a non-oxidizing atmosphere to substantially remove the uniform oxide film existing in the bonding interface.

2. A method for producing a bonded wafer according to claim 1, wherein a thickness of the thinned wafer for active layer is not more than 500 nm.

3. A method for producing a bonded wafer according to claim 1, wherein forming a uniform oxide film comprises thermal oxidation.

4. A method for producing a bonded wafer according to claim 1, wherein an oxygen concentration of at least one of the wafer for active layer and the wafer for support substrate is not more than 1.6×10¹⁸ atoms/cm³.

5. A method for producing a bonded wafer according to claim 1, wherein the thinning of the wafer is conducted by using a hydrogen ion implantation-isolation method or an etching/polishing stop method through an oxygen ion implantation.

6. A method for producing a bonded wafer according to claim 1, wherein the heat treatment is conducted within a temperature range of from 1050° C. to 1250° C. for from 0.5 to 50 hours.

7. A method for producing a bonded wafer according to claim 1, wherein the non-oxidizing atmosphere is an atmosphere of Ar, H₂ or a mixed gas thereof.

8. A method for producing a bonded wafer according to claim 1, wherein each of the wafer for active layer and the wafer for support substrate is a silicon single crystal, and each surface of the wafers to be bonded is a different orientation of (100), (110) or (111) face.
